(19) United States
(12) Patent Application Publication
(10) Pub. No.: US 2016/0268034 A1
(43) Pub. Date: Sep. 15, 2016

(54) Planar Magnetic Components and Assemblies

(71) Applicant: BOSE CORPORATION, Framingham, MA (US)

(72) Inventors: Bradford Kyle Subat, Northborough, MA (US); Remco Terwal, West Newton, MA (US); Daniel Hodgkins, Prnceton, MA (US)

(73) Assignee: BOSE CORPORATION, Framingham, MA (US)

(21) Appl. No.: 14/657,466

(22) Filed: Mar. 13, 2015

(51) Int. Cl. H01F 27/06; H01F 27/29; H05K 1/14; H01F 27/28

(52) U.S. Cl. CPC H01F 27/06; H01F 27/2804; H01F 27/29; H05K 1/141; H01F 2027/065

(57) ABSTRACT

A planar magnetic component includes a printed circuit board, a coil formed on one or more electrically conductive metal layers of the printed circuit board, terminals electrically connected to the coil for energizing the coil, and a magnetic core mounted to the printed circuit board for confining magnetic flux of the coil. The printed circuit board defines an alignment feature for engaging with a mating feature on a mating circuit board, thereby to align the planar magnetic component with the mating circuit board.

### BACKGROUND

This disclosure relates to planar magnetic components and assemblies.

Fabricating planar magnetic components on printed circuit boards is a technique that is widely used to create transformers and inductors in power supplies. One advantage of planar magnetics is the fabrication of inductors that are not tall. Printed circuit boards are only as compact as the tallest component on them, and that is often a magnetic component. Additionally, planar designs offer advantages that include windings as part of the printed circuit board layout and excellent repeatability of inductor performance, highly controllable and repeatable leakage inductance, economical assembly, mechanical integrity, and good thermal characteristics. Planar inductor cores allow for automated surface mount style placement. Other advantages include easy creation of winding taps. This allows realization of much more complex filters than can economically be fabricated with conventional wound structures.

FIG. 1A illustrates a printed circuit board 100 for a power supply which, among other components and circuitry, includes a pair of integrated planar inductors 110. Each of the planar inductors 110 is fabricated by forming a continuous spiral planar winding having inner and outer ends that define two terminals which are integrally connect to other circuitry on the printed circuit board 100. Referring to FIG. 1B, the printed circuit board 100 is a multilayer printed circuit board and the coil windings 112 of the inductors 110 are formed on different conductive layers of the printed circuit board 100. The coil turns on each conductive layer are connected with vias. A pair of magnetic core portions 114 are inserted into the apertures 116 which are formed in the printed circuit board 100 for confining magnetic flux generated by current passing through the inductor coils 112.

Such planar magnetics may also be utilized in output filters for audio amplifiers. Exemplary output filter and planar designs are described in U.S. Pat. No. 7,432,793, the complete disclosure of which is incorporated herein by reference.

### SUMMARY

All examples and features mentioned below can be combined in any technically possible way.

In one aspect, a planar magnetic component includes a printed circuit board, a coil formed on one or more electrically conductive metal layers of the printed circuit board, terminals electrically connected to the coil for energizing the coil, and a magnetic core mounted to the printed circuit board for confining magnetic flux of the coil. The printed circuit board defines an alignment feature for engaging with a mating feature on a mating circuit board, thereby to align the planar magnetic component with the mating circuit board.

Implementations may include one of the following features, or any combination thereof.

In some implementations, the coil includes a plurality of turns disposed among a plurality of conductive layers of the PCB.

In certain implementations, the alignment feature is configured for mechanically coupling the printed circuit board to a mating circuit board such that printed circuit board is arranged substantially perpendicular to the mating circuit board.

In some examples, the alignment feature includes a spring arm for mechanically coupling the PCB to the mating circuit board.

In certain examples, the spring arm includes a barb to engage an aperture in the mating circuit board thereby to inhibit extraction of the printed circuit board from the mating circuit board.

In some cases, the spring arm includes one or more metal layers.

In certain cases, the terminals are located along a first edge of the printed circuit board. The first edge is arranged to face a surface of the mating circuit board when the planar magnetic component is aligned with the mating circuit board.

In some implementations, the terminals are located in respective recesses formed along the first edge of the printed circuit board.

In certain implementations the printed circuit board defines a first aperture, a second aperture, and a third aperture. The coil includes a first coil substantially surrounding the first aperture and a second coil substantially surrounding the second aperture. The magnetic core includes a first leg passing through the first aperture, a second leg passing through the second aperture, and a third leg passing through the third aperture.

In some examples, the third leg of the magnetic core has a gap.

In certain examples, the alignment feature includes a tongue formed in the printed circuit board for engaging a groove in the mating circuit board.

In another aspect, a planar magnetic assembly includes a plurality of flexible joints and a plurality of planar magnetic components coupled to one another via the plurality of flexible joints. Each of the plurality of planar magnetic components includes a printed circuit board segment. Each of the printed circuit board segments have a coil formed on one or more electrically conductive layers of the corresponding printed circuit board segment, and terminals that are electrically connected to the coil for energizing the coil. Each planar magnetic components is also provided with a magnetic core mounted to the corresponding printed circuit board segment for confining magnetic flux of the coil. At least one of the printed circuit board segments defines an alignment feature for engaging with a mating feature in a mating circuit board, thereby to align the planar magnetic assembly with the mating circuit board.

Implementations may include one of the above and/or below features, or any combination thereof.

In some implementations, the alignment feature is configured for mechanically coupling the planar magnetic assembly to the mating circuit board such that the plurality of printed circuit board segments are arranged substantially perpendicular to the mating circuit board.

In certain implementations, the flexible joints are formed from one or more layers of the printed circuit board segments.

In some examples, the flexible joints are formed of one or more exposed metal layers of the printed circuit board segments.

In certain examples, the flexible joints and the printed circuit board segments are integrally formed in a flex-rigid construction comprising one or more flexible polyimide layers which form the flexible joints.

In some cases, the planar magnetic assembly also includes one or more rigid segments disposed between the printed circuit board segments and coupled to the printed circuit board segments via the flexible joints. The one or more rigid segments may define a protrusion for aligning with a mating aperture in the mating circuit board.

In certain cases, the terminals are located along respective first edges of the printed circuit board segments, and the first edges are arranged to face a surface of the mating circuit board when the planar magnetic assembly is aligned with the mating circuit board.

In some implementations, the terminals are located in respective recesses formed along the first edges of the printed circuit board segments.

In certain implementations, at least one of the printed circuit board segments defines a first aperture, a second aperture, and a third aperture. The coil associated with the at least one of the printed circuit board segments includes a first coil substantially surrounding the first aperture and a second coil substantially surrounding the second aperture. The magnetic core associated with the at least one of the printed circuit board segments comprises a first leg passing through the first aperture, a second leg passing through the second aperture, and a third leg passing through the third aperture.

In some examples, each printed circuit board segment is an individual printed circuit board, and the planar magnetic assembly also includes a frame which defines the flexible joints and a plurality of printed circuit board receptacles for receiving and supporting the printed circuit board segments.

In certain examples, the flexible joints are configured to allow the printed circuit board segments to be arranged parallel to each other thereby allowing the planar magnetic assembly to be aligned with the mating circuit board in a serpentine pattern.

According to another aspect, a planar magnetic assembly includes a plurality of planar magnetic components and a frame. Each of the plurality of planar magnetic components includes a printed circuit board having a coil formed on one or more electrically conductive layers of the corresponding printed circuit board segment, and terminals electrically connected to the coil for energizing the coil. Each of the planar magnetic components also includes a magnetic core mounted to the corresponding printed circuit board segment for confining magnetic flux of the coil. The frame receives and supports the plurality of printed circuit boards substantially parallel to each other. The frame defines an alignment feature for engaging with a mating feature in a mating circuit board, thereby to align the planar magnetic assembly with the mating circuit board.

Implementations may include one of the above and/or below features, or any combination thereof.

In some implementations, the frame includes a plurality of electrically conductive pins for establishing electrical connection between the terminals of the printed circuit boards and the mating circuit board.

In certain implementations, the frame include one or more flexible joints, and a plurality of printed circuit board receptacles for receiving and supporting the printed circuit boards. The printed circuit board receptacles are connected to each other in a daisy chain configuration via the flexible joints.

In some examples, the flexible joints are arranged and configured to allow the frame to be folded in a serpentine configuration such that the printed circuit boards are arranged substantially parallel to each other when the planar magnetic assembly is aligned with the mating circuit board.

In certain examples, the frame is configured such that the receptacles snap into each other for increased rigidity in the serpentine configuration.

In some cases, the frame further includes features for connecting the printed circuit board receptacles to each other for increased rigidity.

In certain cases, the features for connecting the printed circuit board receptacles to each other include protrusions and apertures for receiving the protrusions.

In yet another aspect, a planar magnetic assembly includes a plurality of planar magnetic components and a frame. Each of the plurality of planar magnetic components includes a printed circuit board having a coil formed on one or more electrically conductive layers of the corresponding printed circuit board segment, and terminals electrically connected to the coil for energizing the coil. Each of the planar magnetic components also includes a magnetic core mounted to the corresponding printed circuit board for confining magnetic flux of the coil. The frame receives and supports the plurality of printed circuit boards substantially parallel to each other. The frame defines a feature for engaging an aperture in a housing thereby to inhibit movement of the planar magnetic assembly relative to the housing.

Implementations may include one of the above features, or any combination thereof.

### BRIEF DESCRIPTION OF THE DRAWINGS

FIG. 1A is a perspective view of a prior art printed circuit board including integrated planar magnetic components.

FIG. 1B is a perspective view of the prior art printed circuit board of FIG. 1A showing an exploded view of one of the integrated planar magnetic components.

FIG. 2A is perspective view of a first implementation of a planar magnetic component in accordance with the present disclosure.

FIG. 2B is an exploded perspective view of the planar magnetic component of FIG. 2A.

FIG. 3 is a front elevation view of a printed circuit board of the planar magnetic component of FIG. 2A.

FIGS. 4A and 4B are top and bottom perspective views, respectively, of a plurality of planar magnetic components mounted to a mating circuit board.

FIG. 5 is a second implementation of a printed circuit board for planar magnetic component.

FIG. 6A is a front elevation view of a first implementation of a planar magnetic assembly.

FIG. 6B is a top plan view of the planar magnetic assembly of FIG. 6A shown in a folded, serpentine configuration.

FIG. 7A is a perspective view of a second implementation of a planar magnetic assembly.

FIG. 7B is a perspective view of the planar magnetic assembly of FIG. 7A shown in a folded, serpentine configuration.

FIG. 8A is a front elevation view of a third implementation of a planar magnetic assembly.

FIG. 8B is a perspective view of the planar magnetic assembly of FIG. 8A shown in a folded, serpentine configuration.

FIG. 9 is a partial, front elevation view of a fourth implementation of a planar magnetic assembly.

FIG. 10 is a partial, front elevation view of a fifth implementation of a planar magnetic assembly.

FIG. 11A is a top plan view of a sixth implementation of a planar magnetic assembly.

FIG. 11B is a top plan view of the planar magnetic assembly of FIG. 11A shown in a folded, serpentine configuration.

FIG. 12 is a perspective view of a seventh implementation of a planar magnetic assembly.

FIG. 13A is a perspective view of a seventh implementation of a planar magnetic assembly.

FIG. 13B is a detailed side view of the planar magnetic assembly of FIG. 13A disposed between a mating circuit board and a housing.

FIG. 14A is a perspective view of a frame for an eighth implementation of a planar magnetic assembly.

FIG. 14B is a perspective view of a planar magnetic assembly including the frame of FIG. 14A.

FIG. 14C is detailed front elevation view of the planar magnetic assembly if FIG. 14B disposed between a mating circuit board and a housing.

FIG. 15A is a perspective view of a frame for a ninth implementation of a planar magnetic assembly.

FIG. 15B is a perspective view of a planar magnetic assembly including the frame of FIG. 15A.

FIG. 15C is detailed front elevation view of the planar magnetic assembly if FIG. 15B disposed between a mating circuit board and a housing.

FIG. 16 is a perspective view of a tenth implementation of a planar magnetic assembly.

FIG. 17 is a perspective view of an eleventh implementation of a planar magnetic assembly.

FIG. 18 is a perspective view showing planar magnetic components which are configured to engage a mating circuit board using a tongue and groove mounting technique.

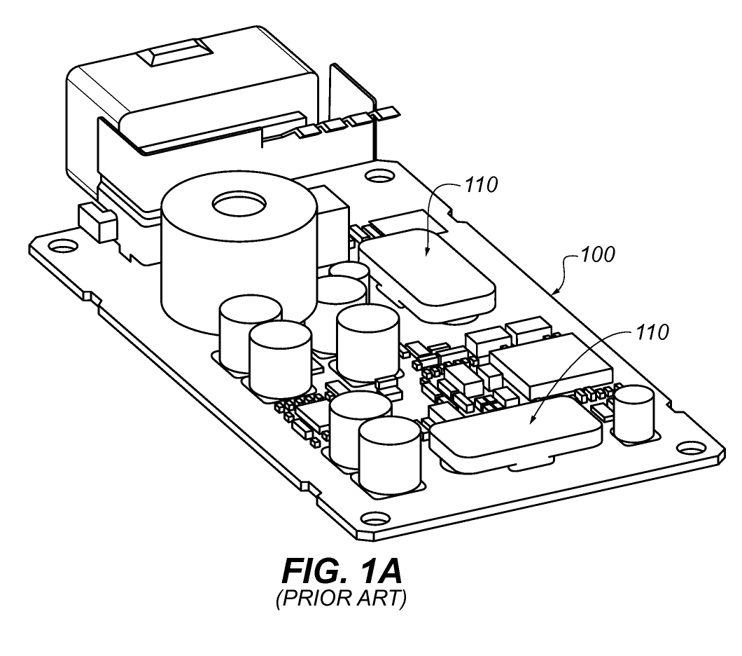

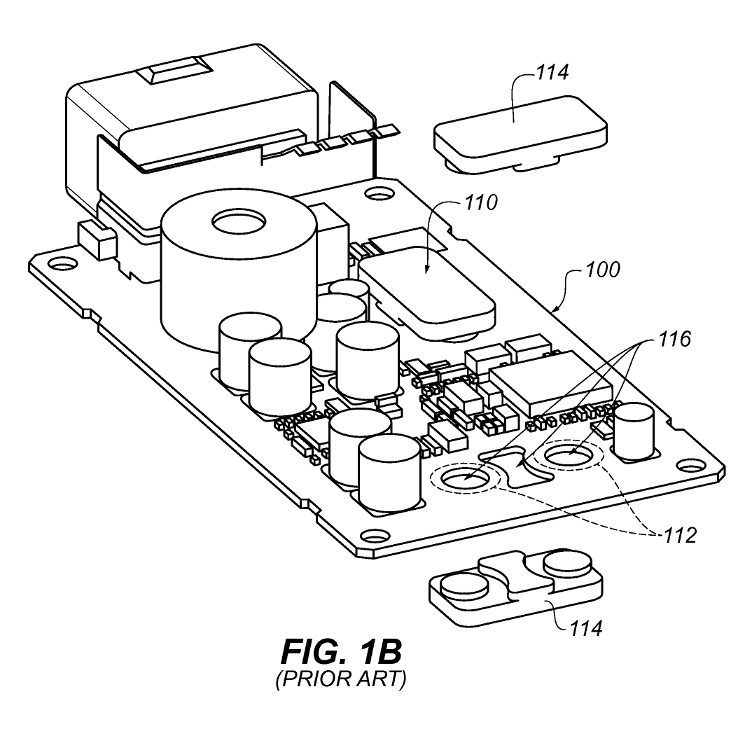

Like reference numerals represent like elements.

### DETAILED DESCRIPTION

This disclosure is based, at least in part, on the realization that it can be beneficial to form planar inductors on separate daughter boards which can be then be mounted vertically to a separate, mating mother board. This allows the daughter boards to have a different electrically conductive (e.g., copper) layer thicknesses and stack-ups, thereby not burdening the mother board with extra thick copper or extra layers.

The use of separate daughter boards for the planar inductors can also potentially save surface area on the mother board and allow for more compact designs. It may also have better performance and offer a cost savings. It can also help to avoid perforation of the ground plane on the mother board possibly negatively affecting EMC integrity of the system. It also allows for the planar magnetic components to be treated as 1-up assembly components that can be altered, without having to change the mother board.

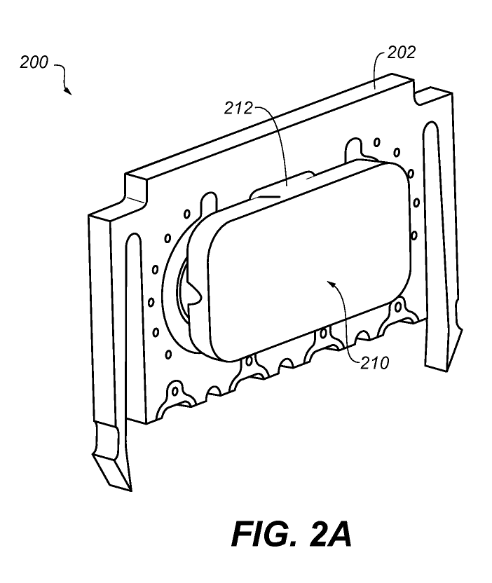

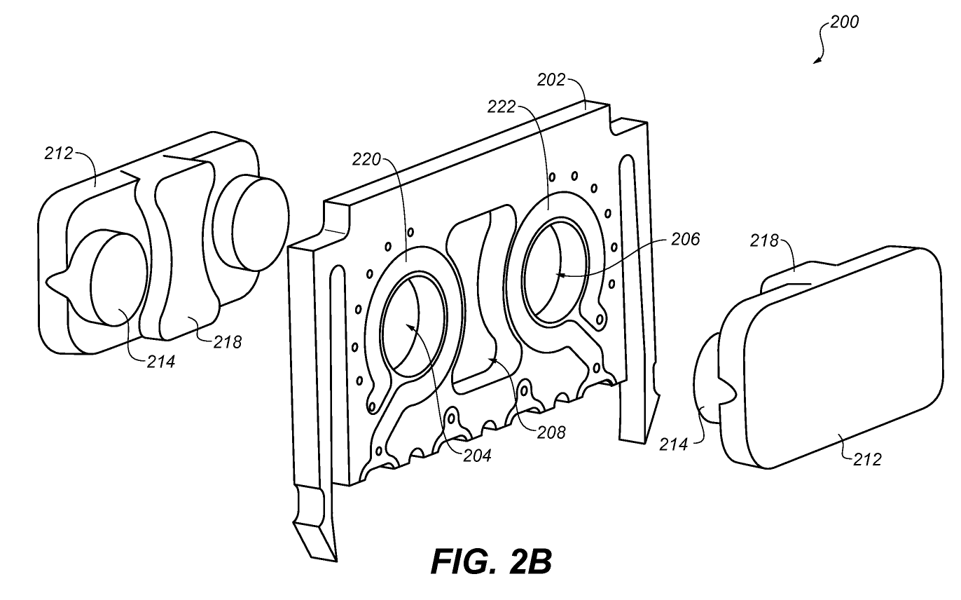

FIGS. 2A and 2B illustrate perspective views of a planar magnetic component in the form of a dual inductor 200 fabricated on a multiple layer printed circuit board 202 including three apertures (i.e., first, second, and third apertures 204, 206, 208 (FIG. 2B)) and a magnetic core 210. Referring to FIG. 2B, in the illustrated example, the magnetic core 210 includes a pair of E-shaped core portions 212 each of which includes a first leg 214 which passes through the first aperture 204, a second leg 216 which passes through the second aperture 206, and a third leg 218 which passes through the third aperture 208. The two core portions 212 can be coupled to each other using various techniques, such as adhesive or a mechanical clip.

The dual inductor 200 includes a first coil 220 which surrounds the first aperture 204 and a second coil 222 which surrounds the second aperture 206. The third aperture 208 is free of a coil. One advantage of the E-shaped core portions 212 is that they provide two magnetic current paths through the magnetic core 210. However, the planar magnetic components are not limited to the particular shape of the cores shown, and it should be appreciated that other core shapes are possible.

In some instances, a gap may be formed at an interface between the respective third legs 218 of the E-shaped core portions 212. A common mode inductance is independent of the gap formed between the third legs 218, and a differential inductance is controlled by the gap. The magnetic field resulting from the differential load current is stored in the gap, and the load current senses the differential inductance. Alternatively, the core may utilize a distributed gap material. For example, the magnetic core may be formed of materials that are loaded with non-magnetic compounds to distribute the gap throughout the core as a whole. The common mode inductance is not affected by the differential load current. This allows a much higher common mode inductance with resulting decrease in common mode noise transmission. The common mode inductance is independently controlled from the differential mode inductance which has benefits in controlling RF emissions in structures where the inductor is part of a class-D filter. The common mode filter pole can be placed much lower than the differential pole potentially resulting in overall lower order filters compared to traditional inductor approaches.

These planar magnetic components may be utilized in output filters for audio amplifiers such as described in U.S. Pat. No. 8,908,887, the complete disclosure of which is incorporated herein by reference.

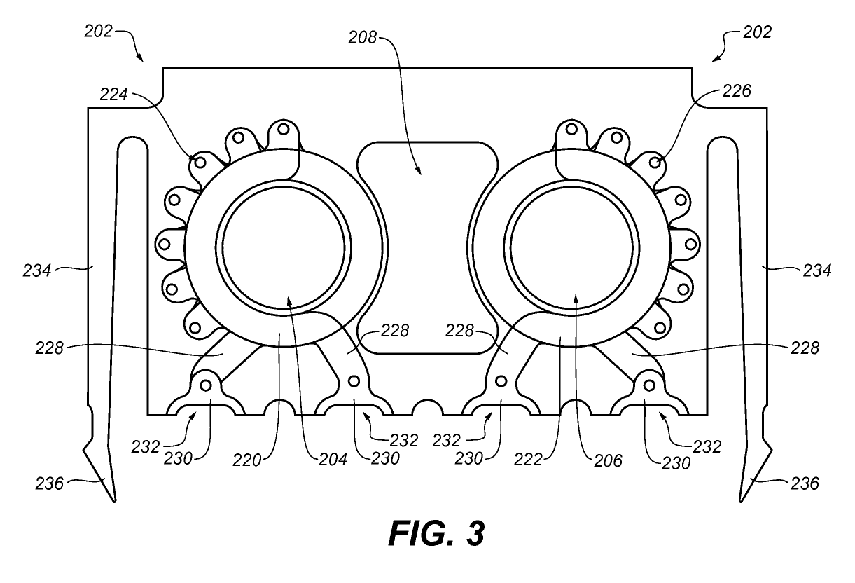

Referring to FIG. 3, the multilayer printed circuit board 202 includes a plurality of layers of electrically conductive material (a/k/a “conductive layers”). The electrically conductive material may be a metal, such as copper. The conductive layers are separated by layers of electrically insulating laminate sheets (a/k/a “insulating layers). The insulating layers may consist of glass-reinforced epoxy laminate sheets, such as FR-4. In the example illustrated in FIG. 3, the multilayer printed circuit board 202 includes eight conductive layers. Each conductive layer defines a pair of coil windings (a/k/a “turns”), one winding associated with the first coil 220 and another associated with the second coil 222.

Metalized through holes known as vias provide electrical connections between the various conductive layers. A first set of vias 224 is associated with the first coil 220, and a second set of vias 226 is associated with the second coil 222. The first and second sets of vias 224, 226 are easily accessible and can be used as taps from the respective coils 220, 222. Conductive traces 228 formed in the first and eighth conductive layers connect the coil windings on the first and eighth conductive layers to respective terminals 230 formed along a bottom edge of the printed circuit board 202. Each terminal 230 is positioned in a local recess 232 formed along the bottom edge of the printed circuit board 202. The local recess 232 is formed initially as an obround hole which is then plated through and partially routed away to expose the terminals 230 along the edge. The terminals 230 allow for an electrical connection to be made to the coils 220, 222.

Using known techniques, the first and second coils 220, 222 and conductive traces 228 can be formed either by chemically etching a layer of electrically conducting material, such as copper, deposited on a face of an electrically insulating laminate sheet, or by depositing electrically conductive material on the face of an electrically insulating laminate sheet.

Notably, the printed circuit board 202 also includes a pair of spring arms 234. The spring arms 234 are integral with the printed circuit board 202 and may be formed (e.g., machined) out of the electrically insulated laminate layers. The spring arms 234 are configured for aligning and mechanically coupling the printed circuit board 202 with a mating circuit board. In that regard, the spring arms 234 include barbed ends 236 for engaging apertures in the mating circuit board.

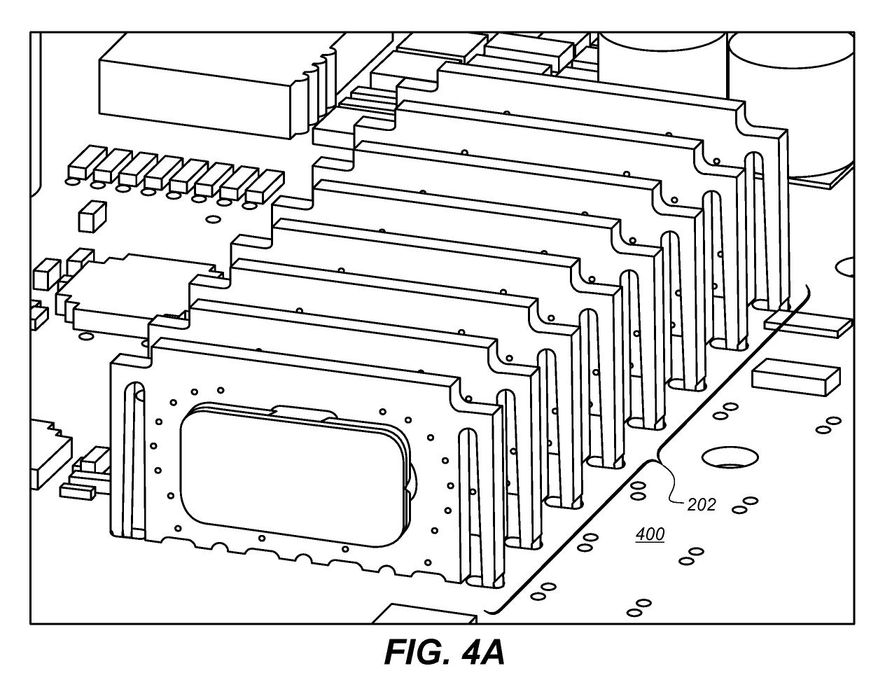

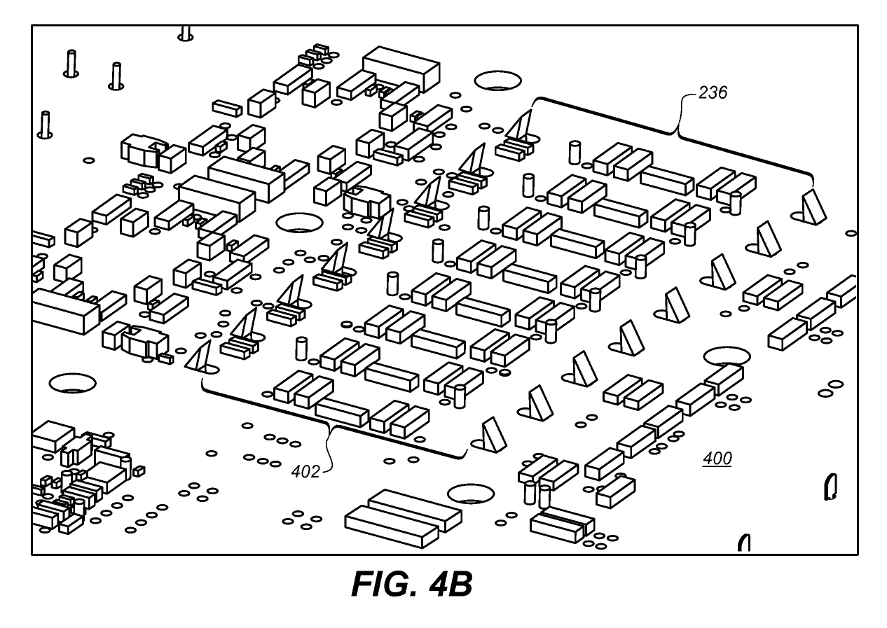

FIGS. 4A and 4B illustrate a plurality of planar magnetic components 200, each having a construction in accordance with FIGS. 2A and 2B, which are mechanically secured to a mating circuit board 400. In the illustrated example, the mating circuit board 400 is a mother board of an audio amplifier. As shown in FIG. 4B, the barbed ends 236 of the spring arms 234 engage apertures 402 in the mating circuit board 400 to mechanically couple the printed circuit boards 202 to the mating circuit board 400 such that the planar magnetic components 200 are arranged substantially perpendicular to the mating circuit board 400 (i.e., such that the conductive layers of the printed circuit boards 202 are substantially perpendicular to conductive layers of the mating circuit board 400).

The spring arms 234 assist in holding the printed circuit boards 202 in place relative to the mating circuit board 400 during the soldering process, and also provide for added structural stability to help inhibit strain on the solder joints when the amplifier is in use. In that regard, the spring arms 234 can assist in keeping the terminals 230 (FIG. 3) aligned with corresponding surface mount pads on the mating circuit board 400. The recesses 232 (FIG. 3) formed along the bottom edges of the printed circuit boards 202 can help to accommodate solder paste which can be reflowed to provide respective solder joints between the terminals 230 on the printed circuit boards 202 and the surface mount pads on the mating circuit board 400.

Having the planar magnetic components on separate printed circuit boards (“daughter boards”) can allow for heavier copper weight to be used for the copper forming the coils without the burden and expense of utilizing the heavier copper weight on the entirety of the mother board. It can also allow for the printed circuit board (daughter board) to carry additional copper layers, for achieving the desired numbers of coil turns, without encumbering the mother board with additional copper layers. This can be a significant cost savings as much of the additional copper layers may otherwise go unutilized on the mother board. Having the planar magnetic components on separate printed circuit boards can also allow the planar magnetic components to be mounted perpendicular to the mother board which can help to reduce the surface area of the mother board for a smaller packaging footprint.

Other Implementations

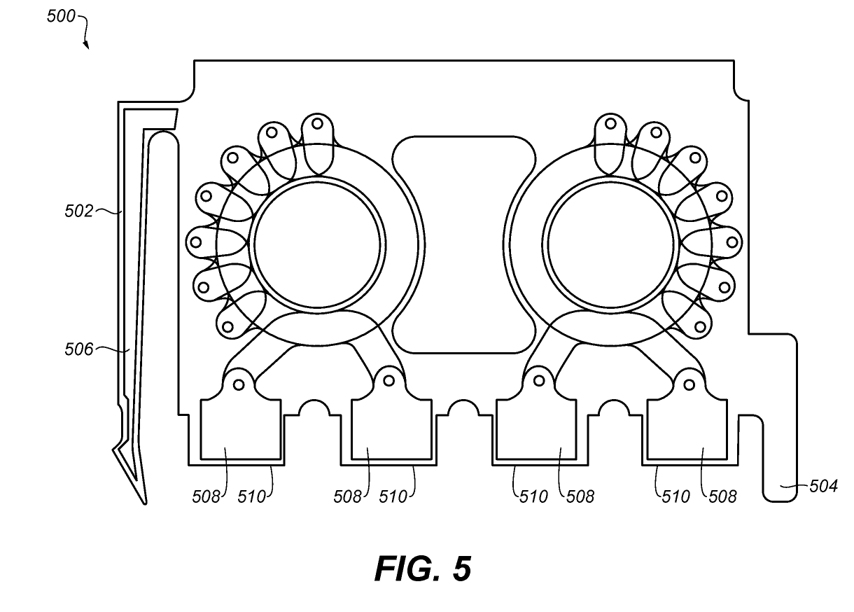

FIG. 5 is another embodiment of a printed circuit board 500 that includes one or more alternative or additional features. The printed circuit board 500 of FIG. 5 includes single spring arm 502 along with an alignment pin 504 which is configured to rest in a corresponding aperture in the mother board to assist in aligning the printed circuit board 500 with the mating circuit board. One or more regions of the conductive material 506 may be included in the spring arm 502 for added stiffness. In this example, terminals 508 are provided by regions of exposed metal on protrusions (pins) 510 formed along the bottom edge of the printed circuit board 500. These protrusions 510 can be received in plated through holes in the mother board and soldered in place to form an electrical connection therebetween. Other reference numbers in FIG. 5 refer to correspondingly numbered elements in previous figures.

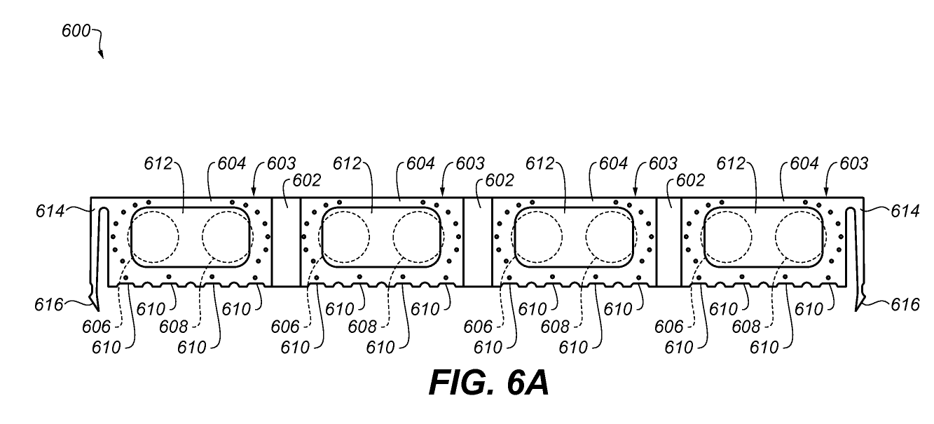

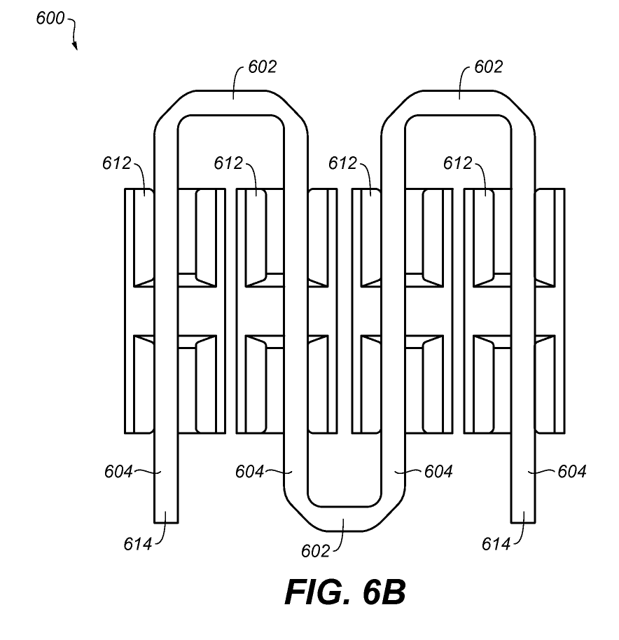

FIG. 6A illustrates an implementation of a planar magnetic assembly 600. The planar magnetic assembly 600 includes a plurality of flexible joints 602 (e.g., living hinges), and a plurality of planar magnetic components 603 which are coupled to each other in a daisy chain configuration via the plurality of flexible joints 602. Each of the planar magnetic components 603 comprises a corresponding printed circuit board segment 604 which can include a dual inductor having a construction as discussed above with respect to FIGS. 2A, 2B, and 3. That is, each of the printed circuit board segments 604 includes a pair of coils 606, 608 formed on the conductive layers of the corresponding printed circuit board segment 604, terminals 610 electrically connected to the coils 606, 608 for energizing the coils 606, 608. Each of the planar magnetic components 603 also includes a magnetic core 612 mounted to the corresponding printed circuit board segment 604 for confining magnetic flux of the coils 606, 608.

In some implementations, the flexible joints 602 may be integral with the printed circuit board segments 604. That is, the flexible joints 602 may consist of localized regions of reduced thickness in a common printed circuit board that also forms each of the individual printed circuit board segments 604. For example, the flexible joints 602 may be formed by removing all but a single layer of conductive material in the localized regions on the common printed circuit board; e.g., leaving behind a single flexible metal layer between adjacent printed circuit board segments.

Alternatively, the flexible joints 602 and the printed circuit board segments 604 may be integrally formed in a flex-rigid construction that includes one or more flexible layers (e.g., flexible polyimide) which form the flexible joints 602 between the relatively rigid printed circuit board segments 604. Alternatively, each of the printed circuit board segments 604 may be an individual printed circuit board and the flexible joints 602 may be formed by over molding sections of a flexible material, such as an elastomer, between adjacent ones of the printed circuit board segments 604.

At least one of the printed circuit board segments 604 can include a feature for mechanically coupling the planar magnetic assembly 600 to a mating circuit board. In the example illustrated in FIG. 6A, a first one of the printed circuit board segments 604 includes a spring arm 614 with a barbed end 616 for engaging an aperture in the mating circuit board. Another barbed spring arm 614 may also be provided at a last one of the printed circuit board segments 604. Additional spring arms could be added for retention or alignment if needed.

The flexible joints 602 allow the printed circuit board segments 604 to be arranged parallel to each other allowing the planar magnetic assembly 600 to be mounted to the mating circuit board in a serpentine pattern (as shown in FIG. 6B).

The ability to fold the planar magnetic assembly 600 in a serpentine arrangement can allows the group of planar magnetic components to fold close to one another so that they do not take much board space on the mating circuit board. This folding also has a secondary benefit in that the linking of the individual daughter boards provides additional mechanical support for the assembly.

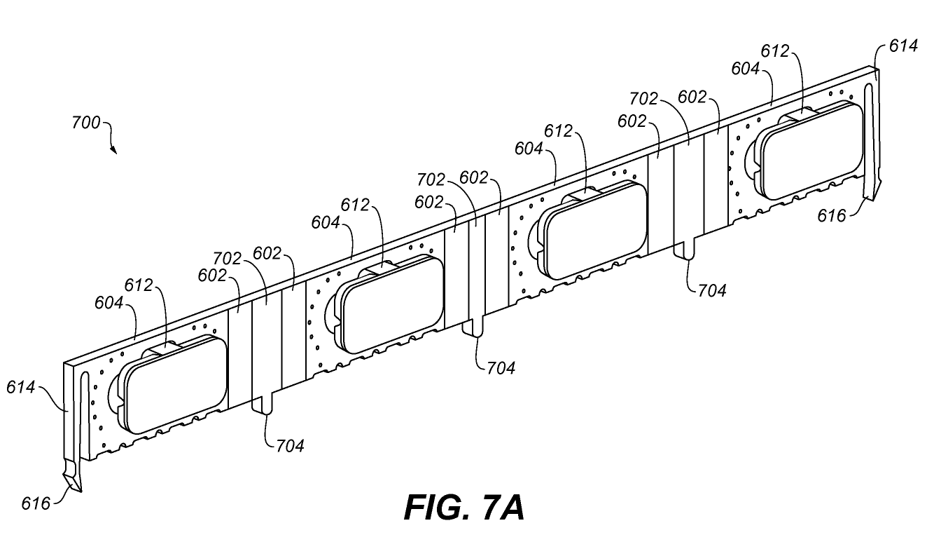

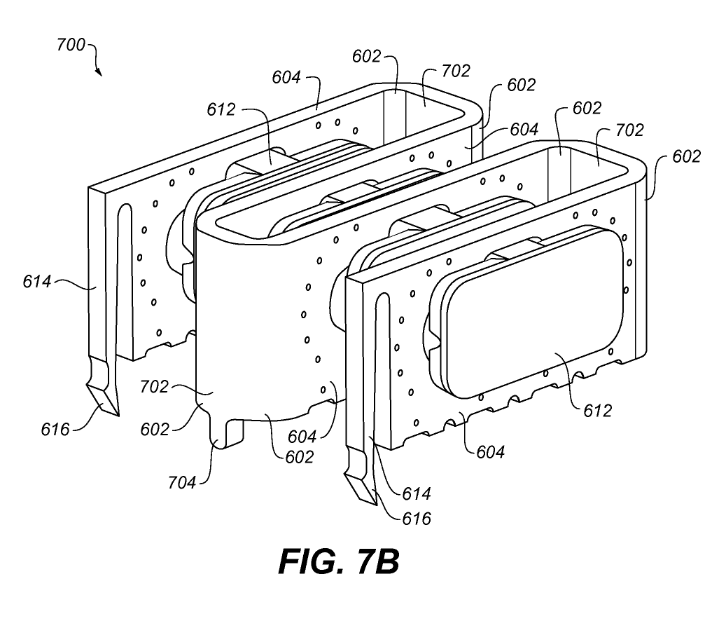

In some instances, as illustrated in FIGS. 7A and 7B, a planar magnetic assembly 700 also includes one or more rigid segments 702 disposed between and coupled to the printed circuit board segments 604 via the flexible joints 602. In the illustrated example, the rigid segments 702 define protrusions 704 for aligning with corresponding apertures on the mating circuit board.

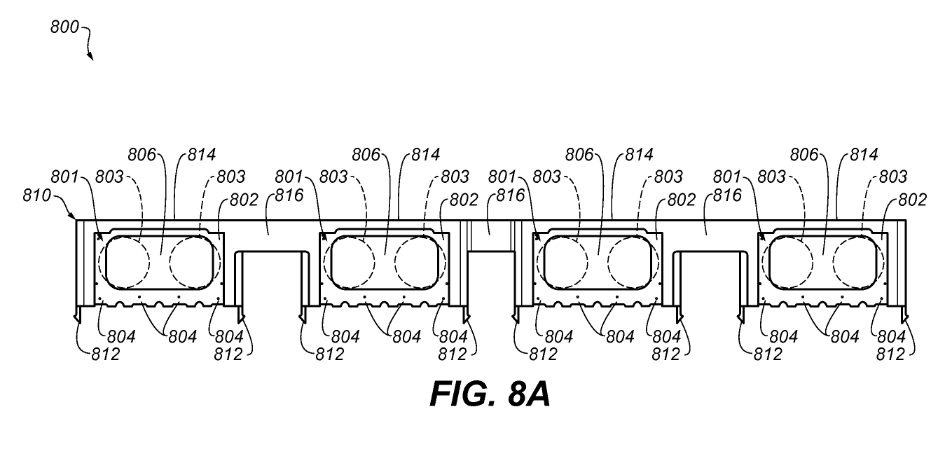

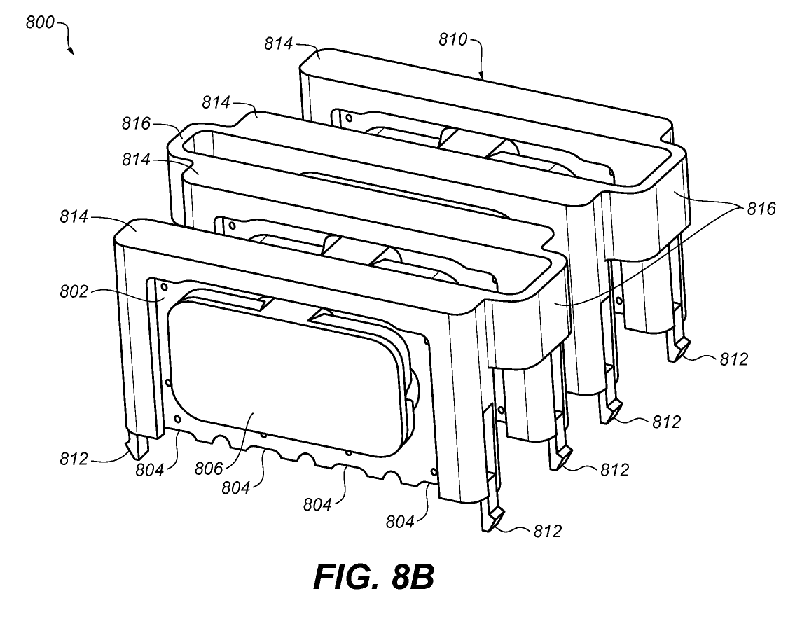

FIGS. 8A and 8B illustrate another implementation of a planar magnetic assembly 800 which includes a plurality of planar magnetic components 801. Each of the planar magnetic components 801 includes a dual inductor that includes a printed circuit board 802 and a magnetic core 806. Each of the printed circuit boards 802 includes a pair of coils 803 formed on one or more electrically conductive layers of the printed circuit board 802, and terminals 804 electrically connected to the coils for energizing the coils. The magnetic core 806 is configured and arranged for confining magnetic flux of the coils.

The planar magnetic assembly 800 also includes a frame 810 for receiving and supporting the plurality of printed circuit boards 802. The frame 810 defines a feature, such as a barbed spring arm 812, for mechanically coupling the plurality of printed circuit boards 802 to a mating circuit board such that the plurality of printed circuit boards 802 are arranged perpendicular to the mating circuit board.

The frame 810 includes a plurality of printed circuit board receptacles 814 for receiving and supporting the printed circuit boards 802. In the example illustrates in FIGS. 8A and 8B, the printed circuit board receptacles 814 slidably receive the printed circuit boards 802 and surround the printed circuit boards 802 along three edges. The terminals 804 are arranged along respective bottom edges of the printed circuit boards 802. In this example, the bottom edges are free of the frame 802 to allow the terminals 804 to establish an electrical connection with the mating circuit board.

The printed circuit board receptacles 814 are connected via flexible joints 816. The flexible joints 816 are arranged and configured to allow the frame 810 to be folded in a serpentine configuration such that the printed circuit boards 802 are arranged substantially parallel to each other when secured to the mating circuit board. The frame 810 can have a molded plastic construction. The spring arms 812, the printed circuit board receptacles 814, and the flexible joints 816 may be integrally formed.

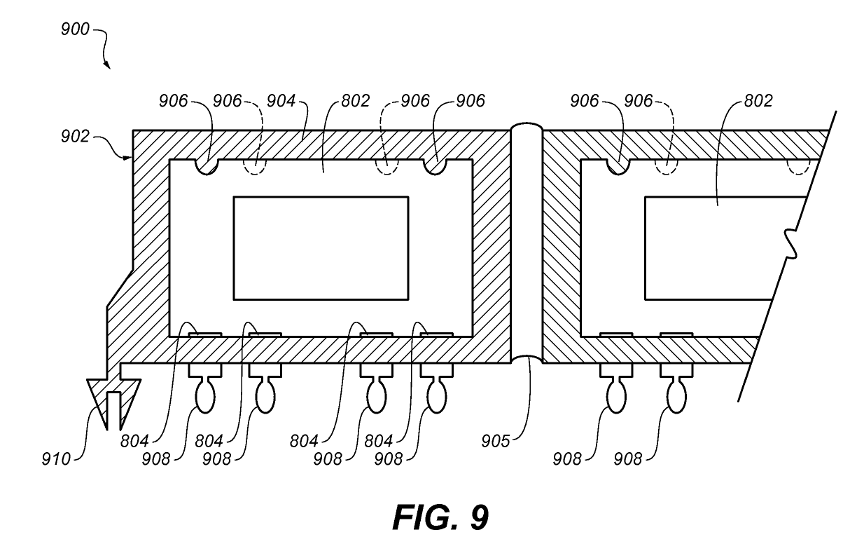

FIG. 9 illustrates another implementation of a planar magnetic assembly 900 that includes a frame 902 that defines a plurality of printed circuit board receptacles 904 which surround the printed circuit boards 802 along all four edges. As in the previous example, the receptacles 904 are connected to each other in a daisy chain configuration via flexible joints 905. In this implementation, the printed circuit boards 802 can snap into place in the printed circuit board receptacles 904, and the receptacles 904 can include tabs 906 for retaining the printed circuit boards 802. In FIG. 9, the printed circuit board receptacles 904 also carry conductive pins 908 which contact the terminals 804 on the printed circuit boards 802 and allow for an electrical connection to be established with the mating circuit board, e.g., via plated through holes on the mating circuit board.

FIG. 9 also illustrates and alternative feature for mechanically coupling the printed circuit boards 802 to the mating circuit board. The feature is in the form of a pair of barbed fingers 910 which protrude from the bottom of the frame 902.

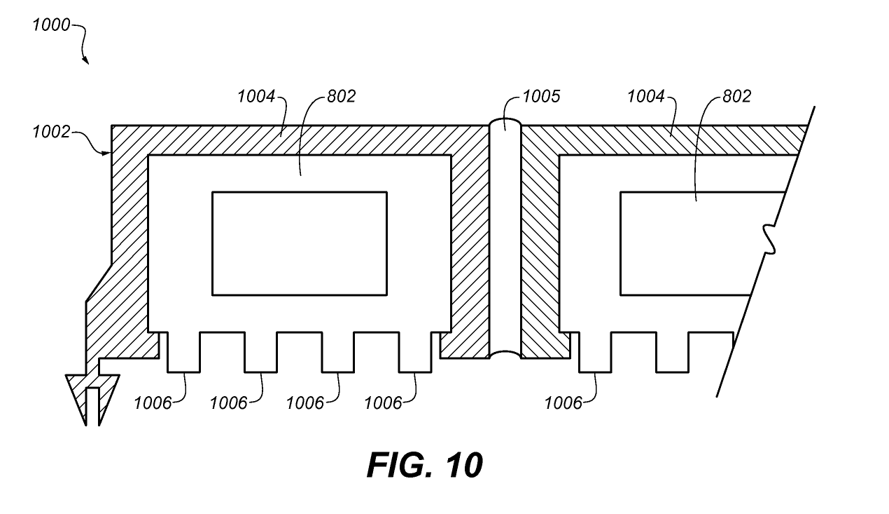

FIG. 10 illustrates another implementation of a planar magnetic assembly 1000 that includes a frame 1002 that defines a plurality of printed circuit board receptacles 1004 connected to each other via flexible joints 1005. The printed circuit board receptacles 1004 are open along bottom edge of the printed circuit boards 802. In this configuration, the terminals are provided by protrusions 1006 formed along the respective bottom edges of the printed circuit boards 802. The protrusions 1006 include one or more regions of exposed conductive materials (e.g., exposed copper) which can be received in plated through holes in the mating circuit board to establish electoral communication therebetween.

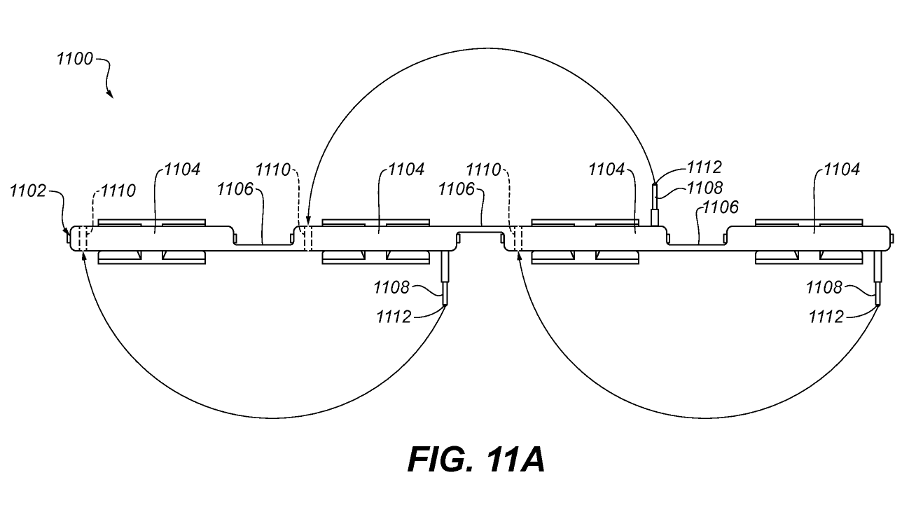

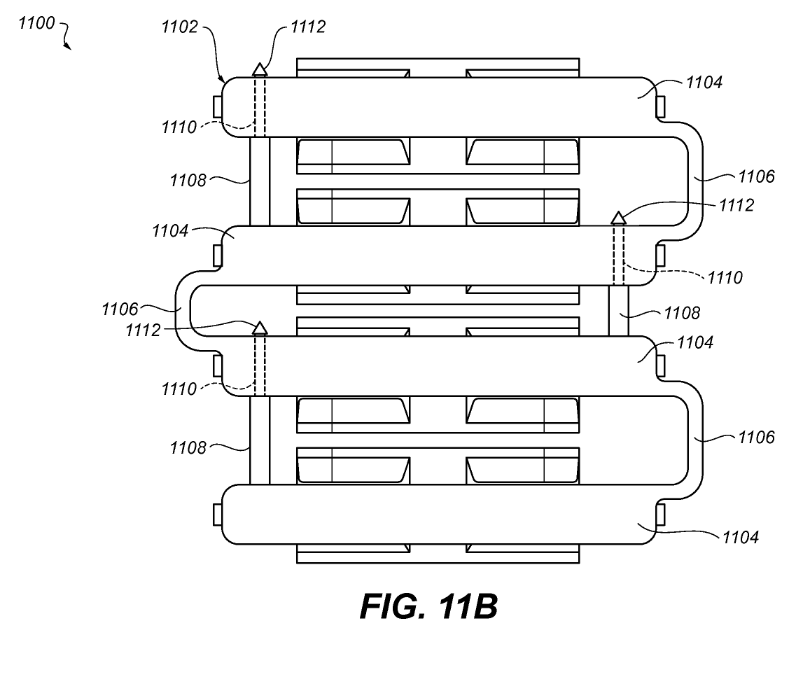

In some cases, the frame may be configured to snap into itself when folded in a serpentine configuration to further increase the rigidity of the planar magnetic assembly 1000. For example, FIGS. 11A and 11B illustrate an implementation of planar magnetic assembly 1100 that includes a frame 1102 that has a plurality of printed circuit board receptacles 1104 which are connected to each other in a daisy chain configuration via flexible joints 1106. Notably, the frame 1102 also includes posts 1108 and apertures 1110 for receiving the posts 1108. In some cases, the posts 1108 may include barbed ends 1112 to lock the posts 1102 in place after they are passed through a mating one of the apertures 1104. Alternatively or additionally, the distal ends of the posts may be formed over after the posts are passed through the apertures 1104 to inhibit removal of the posts from the apertures.

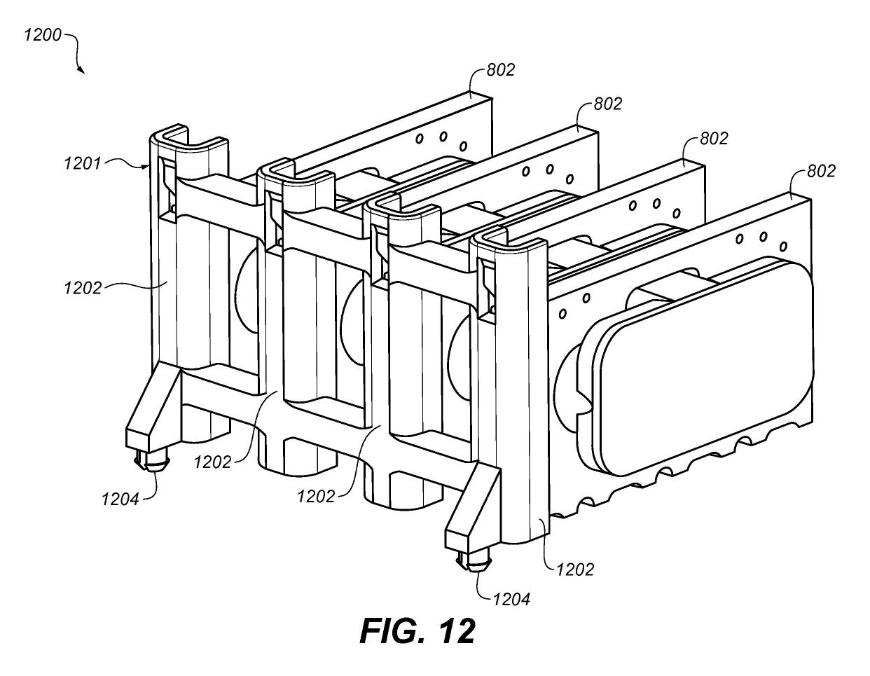

FIG. 12 illustrates another frame configuration for a planar magnetic assembly 1200. In the example illustrates in FIG. 12, a frame 1201 includes a plurality of printed circuit board receptacles 1202 are rigidly connected to each other and are arranged to receive and support the plurality of printed circuit boards 802 in a parallel configuration. As in the examples above, the frame 1201 may include one or more features 1204 (e.g., a barbed post) for mechanically coupling the printed circuit boards 802 to the mating circuit board. As shown, the receptacles 1202 support the printed circuit boards 802 along one edge. If more support is desired, the single side support could instead be configured as a U-shaped receptacles to also the top and opposite side of the printed circuit boards 802.

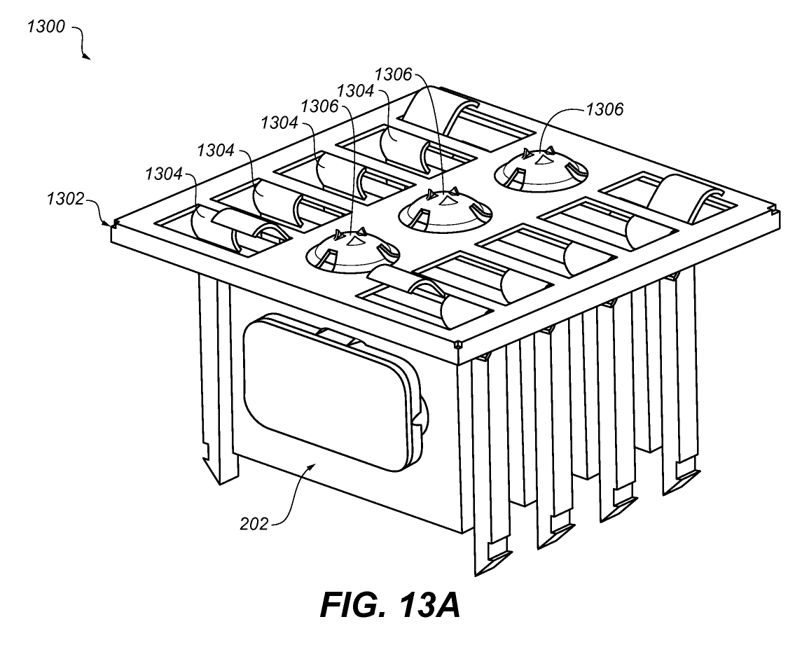

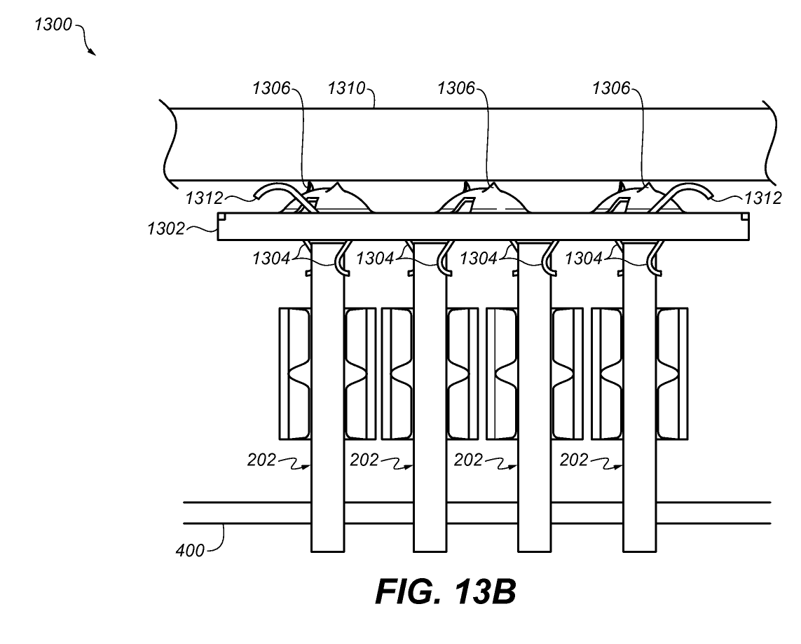

FIGS. 13A and 13B illustrate another planar magnetic assembly 1300 with an alternative frame configuration. The frame 1302 includes a one piece construction that defines a plurality of printed circuit board receptacles in the form of opposing spring fingers 1304 which engage the printed circuit boards 202 and support them in a parallel configuration. The frame 1302 also includes teeth 1306 which are formed on a surface opposite the spring fingers 1304. With reference to FIG. 13B, the teeth 1306 are arranged and configured to grip into an amplifier housing 1310 to prevent movement of the printed circuit boards 202 positioned between the housing 1310 and the amplifier's mother board 400. Spring members 1312 are also provided along the same surface as the teeth 1306. The spring members 1312 are arranged and configured to push against the housing 1310 to help keep the frame engaged with the printed circuit boards 202. The frame 1302 can be formed as a unitary sheet metal part.

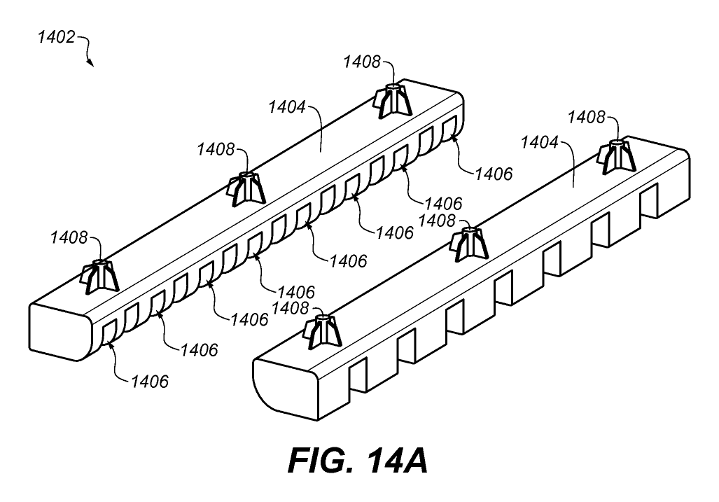

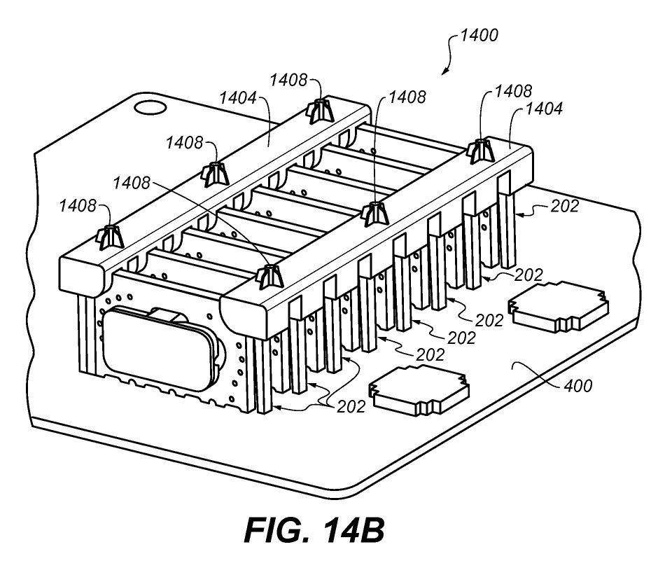

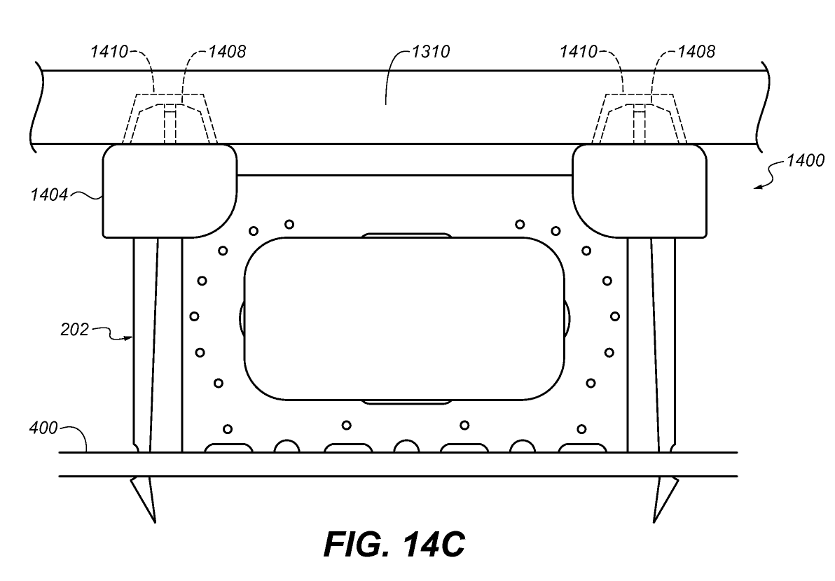

As shown in FIGS. 14A and 14B, illustrate another implementation of a frame 1402 for a planar magnetic assembly 1400 (FIG. 14B). The frame 1402 consists of a pair of racks 1404. Each of the racks 1404 includes a plurality of printed circuit board receptacles 1406 configured to engage upper corners of the printed circuit boards 202 for supporting the printed circuit boards 202 in a parallel configuration with each other. Referring to FIG. 14C, the racks 1404 include posts 1408 for engaging holes 1410 in the amplifier housing 1310 to help prevent movement of the printed circuit boards 202 relative to the mother board 400. The racks 1404 may be molded from plastic.

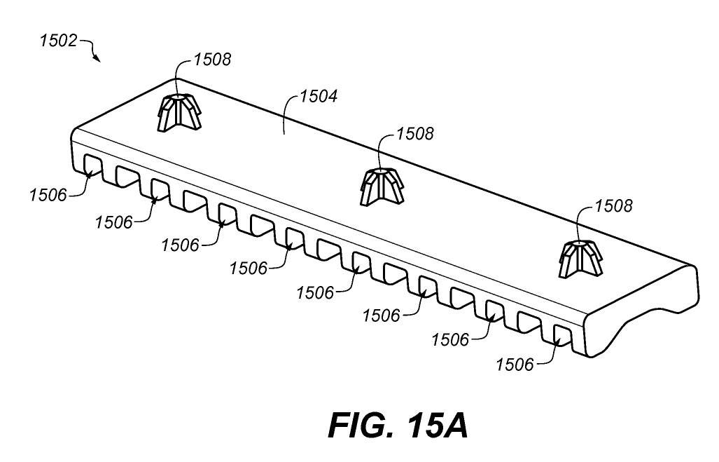

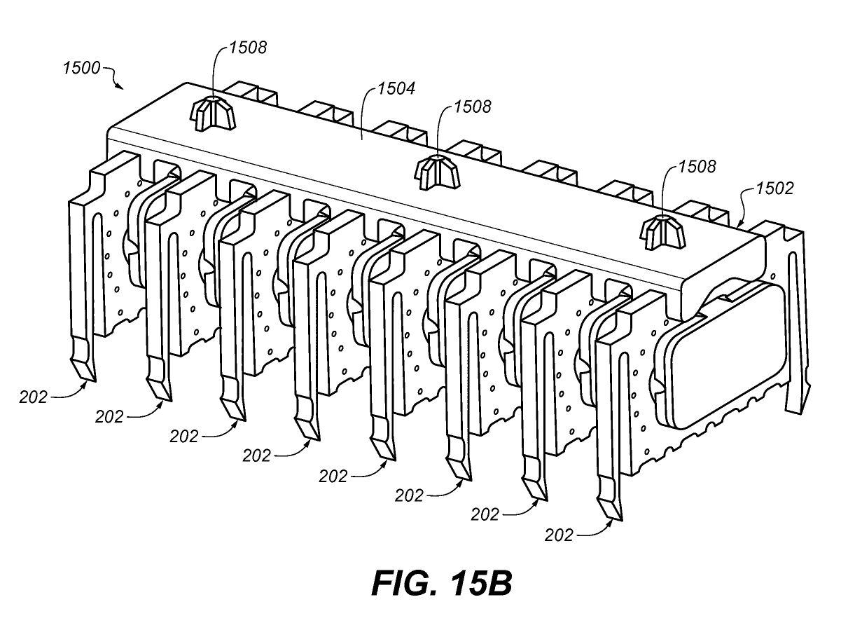

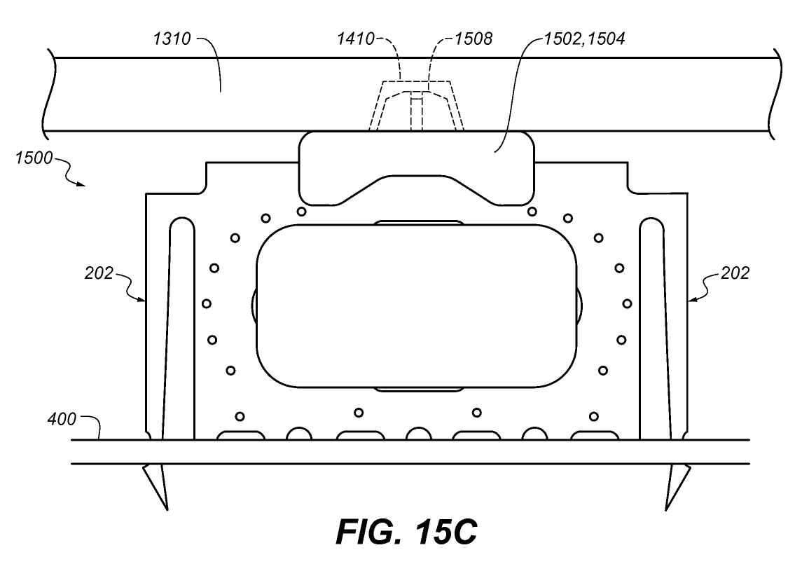

FIGS. 15A and 15B illustrate yet another configuration of a frame 1502 for a planar magnetic assembly 1500 (FIG. 15B). The frame 1502 is in the form of a rack 1504 that defines a plurality of printed circuit board receptacles 1506. The printed circuit board receptacles 1506 are in the form of slots for engaging respective top edges of the plurality of printed circuit boards 202 (FIG. 15B). Referring to FIGS. 15B and 15C, the frame 1502 supports the printed circuit boards 202 in a configuration parallel with each other and perpendicular to the mother board 400 (FIG. 15C). As illustrated in FIG. 15C, the rack 1504 includes posts 1508 that engage holes 1410 in the housing 1310 to prevent movement of the printed circuit boards 202 relative the mother board 400.

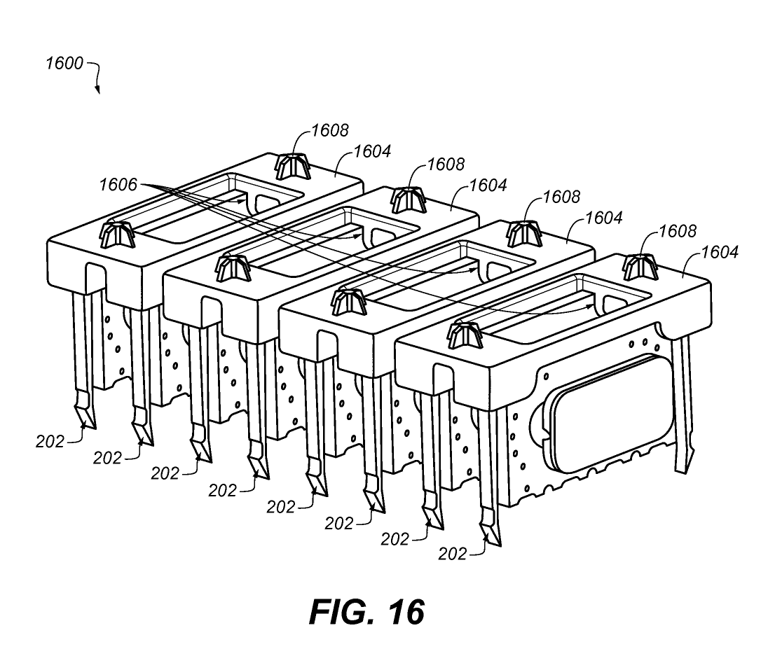

FIG. 16 illustrates yet another implementation of a planar magnetic assembly 1600 that includes a frame consisting of a plurality of smaller (plastic) racks 1604. Each of the racks 1604 includes a pair of receptacles 1606 in the form of slots for engaging the respective top edges of a pair of printed circuit boards 202 for supporting the printed circuit boards 202 in a configuration parallel with each other and perpendicular to the mother board. Each of the racks 1604 also includes posts 1606 for engaging holes in the amplifier housing to help prevent movement of the printed circuit boards 202. A benefit of this configuration is that it is scalable. Since the printed circuit boards will be in pairs, this configuration allows for scaling up as needed. In addition, with this configuration, installation force is reduced as only two printed circuit boards 202 are installed at a time.

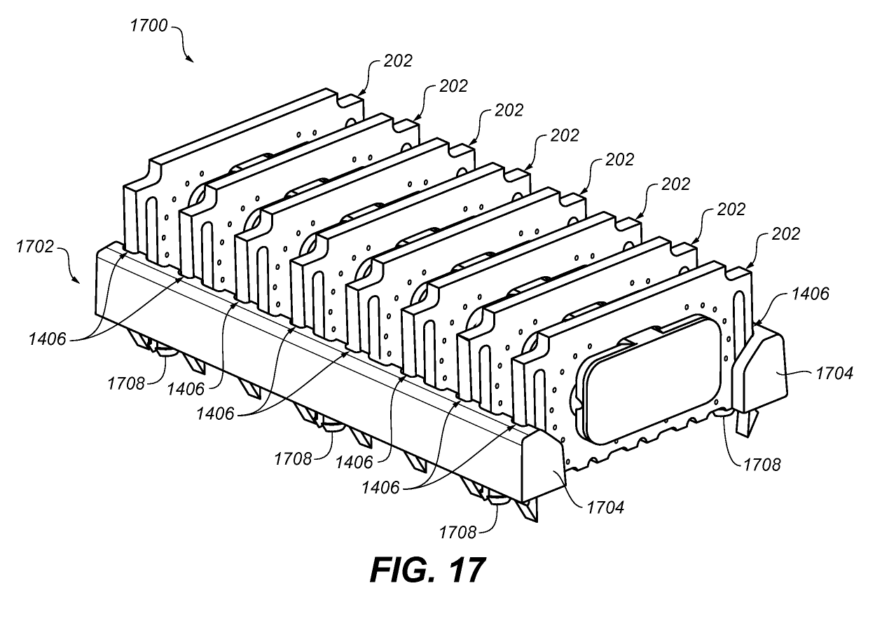

In another configuration, illustrated in FIG. 17, a planar magnetic assembly 1700 includes a plurality of printed circuit boards 202, each of which may have a construction as described above with respect to FIGS. 2A and 2B, and a frame 1702 consisting of a pair of racks 1704 (e.g., plastic racks). Each of the racks 1704 defines a plurality of printed circuit board receptacles 1706 in the form of slots for engaging respective lower side edges of the printed circuit boards 202 for supporting the printed circuit boards 202 in a configuration parallel with each other and perpendicular to the mother board. The racks 1704 define features 1708, shown in the form of barbed fingers, for engaging mating apertures in the mother board, thereby to mechanically couple the printed circuit boards 202 to the mother board.

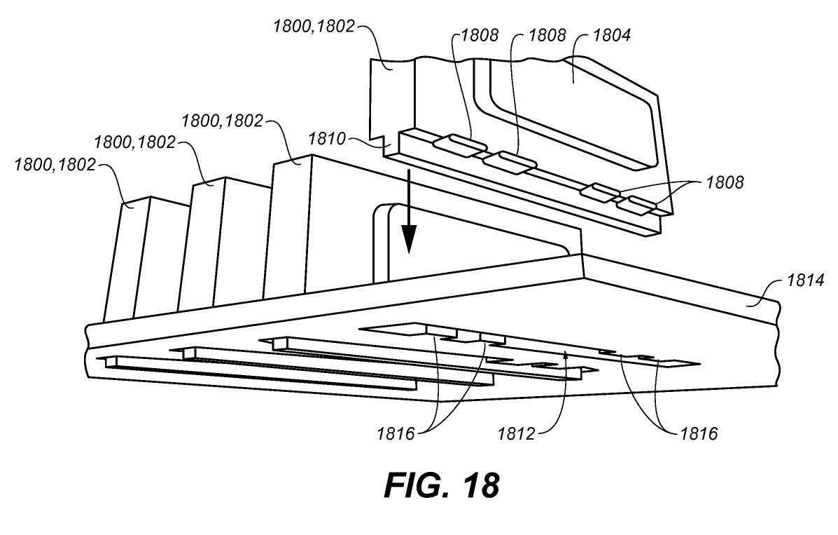

Although various means of aligning planar magnetic components with a mating circuit board have been described, yet another variation is illustrated in FIG. 18. The implementation of FIG. 18 utilizes a tongue and groove mounting technique which allows for surface-to-surface contact between the terminals on the planar magnetic components and surface mount pads on the mating circuit board. The surface-to-surface contact may enable better soldering as well as the ingress of heat to ensure solder melting in a reflow process. It also may allow for direct glue placement from the bottom to offload the solder joints.

Each of the planar magnetic components 1800 includes a dual inductor that includes a printed circuit board 1802 and a magnetic core 1804. Each of the printed circuit boards 1802 includes a pair of coils (not shown) formed on one or more electrically conductive layers of the printed circuit board 1802, and terminals 1808 electrically connected to the coils for energizing the coils.

Each printed circuit board 1802 defines a tongue 1810, a region of reduced printed circuit board thickness, along its bottom edge. The tongue 1810 is received in a mating aperture 1812 in the mating circuit board 1814. The mating circuit board 1814 defines protrusions 1816 which extend into the apertures 1812. The protrusions 1816 align with the terminals 1808 on the printed circuit boards 1802 and carry surface mount pads (not shown) for establishing electrical connection between the printed circuit boards 1802 and the mating circuit board 1814. The protrusions 1816 help to define a groove which runs down the center of the aperture 1812 and which receives the tongue 1810 to keep the planar magnetic components 1800 aligned with the mating circuit board 1814.

Although a plurality of discrete printed circuit boards are illustrated in FIG. 18, similar tongue and groove features could be utilized with print circuit boards connected in a daisy-chain configuration via flexible joints for establishing alignment with a mating circuit board. In such cases, the tongue may be formed in individual printed circuit board segments or it may be formed as a part of a frame.

While a printed circuit board with a dual inductor design has been shown and described other configurations are possible. In some examples, the printed circuit board may only carry a single inductor. And, although a magnetic core comprising a pair of E-shaped core portions has been described, the magnetic core may take other shapes and configurations. Other core shapes also possible, such as U-shaped and I-shaped cores. In some cases, the magnetic cores may be press-fitted into the printed circuit boards. Furthermore, in some instances the planar inductors may be configured as air core inductors and may not include a magnetic core. Some implementations, the printed circuit boards may include more than one coil winding per conductive layer for each inductor.

A number of implementations have been described. Nevertheless, it will be understood that additional modifications may be made without departing from the scope of the inventive concepts described herein, and, accordingly, other implementations are within the scope of the following claims.

1. A planar magnetic component comprising:
a printed circuit board including a spring arm, wherein the spring arm is integral with the printed circuit board and comprises one or more metal layers of the printed circuit board for added stiffness;
a coil formed on one or more electrically conductive metal layers of the printed circuit board;
terminals electrically connected to the coil for energizing the coil; and
a magnetic core mounted to the printed circuit board for confining magnetic flux of the coil,
wherein the spring arm defines an alignment feature for engaging with a mating feature in a mating circuit board, thereby to align and mechanically couple the planar magnetic component with the mating circuit board.

2. The planar magnetic component of claim 1, wherein the coil comprises a plurality of turns disposed among a plurality of conductive layers of the PCB.

3. The planar magnetic component of claim 1, wherein the alignment feature is configured for mechanically coupling the printed circuit board to the mating circuit board such that printed circuit board is arranged substantially perpendicular to the mating circuit board.

4. (canceled)

5. The planar magnetic component of claim 1, wherein the spring arm comprises a barb to engage an aperture in the mating circuit board thereby to inhibit extraction of the printed circuit board from the mating circuit board.

6. (canceled)

7. The planar magnetic component of claim 1, wherein the terminals are located along a first edge of the printed circuit board, and wherein the first edge is arranged to face a surface of the mating circuit board when the planar magnetic component is aligned with the mating circuit board.

8. The planar magnetic component of claim 7, wherein the terminals are located in respective recesses formed along the first edge of the printed circuit board.

9. The planar magnetic component of claim 1, wherein the printed circuit board defines a first aperture, a second aperture, and a third aperture; wherein the coil comprises a first coil substantially surrounding the first aperture and a second coil substantially surrounding the second aperture; and wherein the magnetic core comprises a first leg passing through the first aperture, a second leg passing through the second aperture, and a third leg passing through the third aperture.

10. The planar magnetic component of claim 9, wherein the third leg of the magnetic core has a gap.

11. The planar magnetic component of claim 1, wherein the alignment feature comprises a tongue formed in the printed circuit board for engaging a groove in the mating circuit board.

12. A planar magnetic assembly comprising:
A. a plurality of flexible joints;
B. a plurality of planar magnetic components coupled to one another via the plurality of flexible joints, each of the plurality of planar magnetic components comprising:
i. a printed circuit board segment comprising:
a. a coil formed on one or more electrically conductive layers of the corresponding printed circuit board segment, and
b. terminals electrically connected to the coil for energizing the coil; and
ii. a magnetic core mounted to the corresponding printed circuit board segment for confining magnetic flux of the coil,
wherein at least one of the printed circuit board segments includes a spring arm integral with the printed circuit board segment, the spring arm comprising one or more metal layers of the printed circuit board segment for added stiffness and defining an alignment feature for engaging with a mating feature in a mating circuit board, thereby to align and mechanically couple the planar magnetic assembly with the mating circuit board.

13. The planar magnetic assembly of claim 12, wherein the alignment feature is configured for mechanically coupling the planar magnetic assembly to the mating circuit board such that the plurality of printed circuit board segments are arranged substantially perpendicular to the mating circuit board.

14. The planar magnetic assembly of claim 12, wherein the flexible joints are formed from one or more layers of the printed circuit board segments.

15. The planar magnetic assembly of claim 14, wherein the flexible joints are formed of one or more exposed metal layers of the printed circuit board segments.

16. The planar magnetic assembly of claim 14, wherein the flexible joints and the printed circuit board segments are integrally formed in a flex-rigid construction comprising one or more flexible polyimide layers which form the flexible joints.

17. The planar magnetic assembly of claim 12, further comprising one or more rigid segments disposed between the printed circuit board segments and coupled to the printed circuit board segments via the flexible joints, wherein the one or more rigid segments define a protrusion for aligning with a mating aperture in the mating circuit board.

18. The planar magnetic assembly of claim 12, wherein the terminals are located along respective first edges of the printed circuit board segments, and wherein the first edges are arranged to face a surface of the mating circuit board when the planar magnetic assembly is aligned with the mating circuit board.

19. The planar magnetic assembly of claim 18, wherein the terminals are located in respective recesses formed along the first edges of the printed circuit board segments.

20. The planar magnetic assembly of claim 12, wherein at least one of the printed circuit board segments defines a first aperture, a second aperture, and a third aperture;
wherein the coil associated with the at least one of the printed circuit board segments comprises a first coil substantially surrounding the first aperture and a second coil substantially surrounding the second aperture; and
wherein the magnetic core associated with the at least one of the printed circuit board segments comprises a first leg passing through the first aperture, a second leg passing through the second aperture, and a third leg passing through the third aperture.

21. The planar magnetic assembly of claim 12, wherein each printed circuit board segment is an individual printed circuit board, and wherein the planar magnetic assembly further comprises a frame which defines the flexible joints and a plurality of printed circuit board receptacles for receiving and supporting the printed circuit board segments.

22. The planar magnetic assembly of claim 12, wherein the flexible joints are configured to allow the printed circuit board segments to be arranged parallel to each other thereby allowing the planar magnetic assembly to be aligned with the mating circuit board in a serpentine pattern.

23. A planar magnetic assembly comprising:
A. a plurality of planar magnetic components, each of the plurality of planar magnetic components comprising:
i. a printed circuit board comprising a coil formed on one or more electrically conductive layers of the corresponding printed circuit board segment, and terminals electrically connected to the coil for energizing the coil, and
ii. a magnetic core mounted to the corresponding printed circuit board segment for confining magnetic flux of the coil; and
B. a frame for receiving and supporting the plurality of printed circuit boards substantially parallel to each other,
wherein the frame includes spring arms that are integral with the frame, and wherein each spring arm comprises one or more metal layers of the printed circuit board segment for added stiffness and defines an alignment feature for engaging with a mating feature in a mating circuit board, thereby to align the planar magnetic assembly with the mating circuit board.

24. The planar magnetic assembly of claim 23, wherein the alignment feature is configured for mechanically securing the planar magnetic assembly to a mating circuit board such that the plurality of printed circuit boards are arranged substantially perpendicular to the mating circuit board.

25. The planar magnetic assembly of claim 24, wherein the alignment feature comprises one or more barbs for engaging an aperture on the mating circuit board for mechanically securing the plurality of printed circuit boards to the mating circuit board.

26. The planar magnetic assembly of claim 23, wherein the terminals are located along respective first edges of the printed circuit boards, and wherein the first edges are arranged to face a surface of the mating circuit board when the planar magnetic component is mechanically coupled to the mating circuit board.

27. The planar magnetic assembly of claim 23, wherein the frame includes a plurality of electrically conductive pins for establishing electrical connection between the terminals of the printed circuit boards and the mating circuit board.

28. The planar magnetic assembly of claim 23, wherein the frame comprises one or more flexible joints; and a plurality of printed circuit board receptacles for receiving and supporting the printed circuit boards, wherein the printed circuit board receptacles are connected to each other in a daisy chain configuration via the flexible joints.

29. The planar magnetic assembly of claim 28, wherein the flexible joints are arranged and configured to allow the frame to be folded in a serpentine configuration such that the printed circuit boards are arranged substantially parallel to each other when the planar magnetic assembly is aligned with the mating circuit board.

30. The planar magnetic component of claim 29, wherein the frame is configured such that the receptacles snap into each other for increased rigidity in the serpentine configuration.

31. The planar magnetic component of claim 29, wherein the frame further comprises features for connecting the printed circuit board receptacles to each other for increased rigidity.

32. The planar magnetic component of claim 31, wherein the features for connecting the printed circuit board receptacles to each other comprise protrusions and apertures for receiving the protrusions.

33. A planar magnetic assembly comprising:
A. a plurality of planar magnetic components, each of the plurality of planar magnetic components comprising:
i. a printed circuit board comprising a coil formed on one or more electrically conductive layers of the corresponding printed circuit board, and terminals electrically connected to the coil for energizing the coil, and
ii. a magnetic core mounted to the corresponding printed circuit board for confining magnetic flux of the coil; and
B. a frame for receiving and supporting the plurality of printed circuit boards substantially parallel to each other,
wherein the frame includes spring arms that are integral with the frame, and wherein each spring arm comprises one or more metal layers of the printed circuit board segment for added stiffness and defines a feature for engaging an aperture in a housing thereby to inhibit movement of the planar magnetic assembly relative to the housing.
